(19) United States
(12) Patent Application Publication
(10) Pub. No.: US 2023/0268717 A1
(43) Pub. Date: Aug. 24, 2023

(54) LOW COST DISCRETELY TUNABLE LASER SYSTEM WITH STABILIZATION

(71) Applicant: CORNING INCORPORATED, Corning, NY (US)

(72) Inventor: Anthony Sebastian Bauco, Horseheads, NY (US)

(21) Appl. No.: 18/110,587

(22) Filed: Feb. 16, 2023

Related U.S. Application Data
(60) Provisional application No. 63/313,098, filed on Feb. 23, 2022.

(51) Int. Cl. H01S 5/0687; H01S 5/14

(52) U.S. Cl. CPC H01S 5/0687; H01S 5/141

(57) ABSTRACT

Discretely tunable laser systems include a continuously tunable laser for outputting a beam tunable among selectable frequencies, the selectable frequencies are separated in frequency by discrete frequency intervals, the discrete frequency intervals include a maximum interval and a minimum interval, where a difference between the maximum interval and the minimum interval is 100 MHz or less, and an external stabilization circuit coupled to the continuously tunable laser and a controller. The external stabilization circuit includes a first photodiode generating a first signal corresponding to a portion of the beam and an interferometer that produces resonances upon incidence of another portion of the beam. The resonances are equally spaced in frequency, with each defining one of the selectable frequencies. A second photodiode generates a second signal corresponding a transmission beam generated by the interferometer. The controller tunes the continuously tunable laser among the selectable frequencies based on the first and second signals.

This application claims the benefit of priority under 35 U.S.C § 120 of U.S. Provisional Application Ser. No. 63/313,098 filed on Feb. 23, 2022, the content of which is relied upon and incorporated herein by reference in its entirety.

### TECHNICAL FIELD

The present disclosure generally relates to discretely tunable laser systems with stabilization, and more specifically to systems and methods that implement an externally optically coupled Fabry-Pérot interferometer and proportional-integral-derivative (PID) controller to keep a continuously tunable laser locked to a Fabry-Pérot resonance edge, thereby achieving precise steps in frequency.

### BACKGROUND

Devices such as multi-surface profilers (MSP), which are frequency stepping interferometers that provide fast and accurate metrology for components such as semiconductor wafers, have very specific requirements for discrete tuning. Other devices, such as telecommunication devices, may use discretely tunable lasers to drive optical channels that are precisely spaced. In such devices, for example, the laser needs to be tuned in discrete steps of equally spaced frequencies and the steps should be consistent to within +/−100 MHz or less with respect to each other. Current MSPs use coupled cavity laser systems. A coupled cavity laser system is a laser diode with an external cavity that feeds back a portion of the laser diode output into the laser diode by reflecting the light off a holographic grating. The holographic grating is used to tune across the gain bandwidth of the laser diode.

The laser diode's internal Fabry-Pérot modes define the discrete wavelengths and/or frequencies. While this system works to some degree, it is inherently unstable and chaotic. For example, small changes in laser diode parameters such as the output coupler reflectivity or the smoothness of the gain profile can result in an unacceptable level of instability. Changes in grating reflectivity or in the length of the external cavity can also send the laser into chaos. Additionally, coupled cavity laser systems are very difficult to operate in a stable regime because the diode cavity of the diode laser sets the step size and there are issues with jumping in frequency between the diode cavity and the external cavity.

Another laser system option is a continuously tunable laser. However, to achieve highly precise steps in frequency, the continuously tunable laser must be combined with a very expensive optical wavelength and frequency meter called a wavemeter. The advantage to using a continuously tunable laser in MSPs is that when they are controlled properly, they are more stable than coupled cavity laser systems.

Accordingly, a need exists for low cost systems and methods to configure continuously tunable lasers to achieve discrete tuning at precise steps in frequency over a range of wavelengths.

### SUMMARY

In a first aspect A1, a discretely tunable laser system includes a continuously tunable laser configured to output a beam tunable among a plurality of selectable frequencies, each of the plurality of selectable frequencies separated in frequency by a plurality of discrete frequency intervals, the plurality of discrete frequency intervals including a maximum frequency interval and a minimum frequency interval, wherein a difference between the maximum frequency interval and the minimum frequency interval is 100 MHz or less. An external stabilization circuit is optically coupled to the continuously tunable laser and electrically coupled to a controller, the controller controlling the tuning of the continuously tunable laser among the plurality of selectable frequencies. The external stabilization circuit includes a first tap configured to split the beam into a first beam and a second beam, a second tap configured to split the second beam into a third beam and a fourth beam; a first photodiode configured to generate a first electrical signal corresponding to a transmission power of the third beam, a Fabry-Pérot interferometer configured to produce a plurality of resonances upon incidence of the fourth beam, the plurality of resonances equally spaced in frequency, each of the plurality of resonances defining one of the plurality of selectable frequencies, the Fabry-Pérot interferometer generating a transmission beam from the fourth beam, and a second photodiode configured to generate a second electrical signal corresponding to a transmission power of the transmission beam from the Fabry-Pérot interferometer. The controller is configured to generate one or more tuning signals for tuning the continuously tunable laser to one of the plurality of selectable frequencies based on the first electrical signal and the second electrical signal, and transmit the one or more tuning signals to the continuously tunable laser thereby causing the continuously tunable laser to output a beam having the one of the plurality of selectable frequencies.

In a second aspect A2, according to the first aspect A1, the one or more tuning signals adjust one or more tuning elements of the continuously tunable laser including at least one of a grating and a laser cavity length for outputting the beam having the one of the plurality of selectable frequencies.

In a third aspect A3, according to any preceding aspect, the controller implements a proportional-integral-derivative (PID) controller configured to control the one or more tuning signals by minimizing an error signal, the error signal is a difference between the second electrical signal corresponding to the transmission power of the transmission beam from the Fabry-Pérot interferometer and an amplitude adjusted first electrical signal of the first electrical signal corresponding to the transmission power of the third beam.

In a fourth aspect A4, according to any preceding aspect, the discretely tunable laser system further includes a differential amplifier configured to receive the amplitude adjusted first electrical signal and the second electrical signal and, in response, generate the error signal.

In a fifth aspect A5, according to any preceding aspect, the external stabilization circuit further includes a third photodiode optically coupled to the transmission beam from the Fabry-Pérot interferometer and configured to generate a third electrical signal corresponding to the transmission power of the transmission beam, wherein the controller is further configured to: receive the third electrical signal, and implement a second PID controller configured to generate a tuning signal for adjusting a cavity length tuning element of the continuously tunable laser based on addition of an RMS value of the third electrical signal and the error signal.

In a sixth aspect A6, according to any preceding aspect, the discretely tunable laser system further includes an isolator optically coupled to the continuously tunable laser and the first tap enabling transmission of light in one direction, from the continuously tunable laser toward the first tap

In a seventh aspect A7, according to any preceding aspect, the continuously tunable laser is at least one of a grating tuned laser, an etalon tuned laser and a microelectromechanical system (MEMS) tunable vertical cavity surface emitting laser (VCSEL).

In an eighth aspect A8, according to any preceding aspect, the Fabry-Pérot interferometer is air spaced.

In a ninth aspect A9, according to any preceding aspect, the plurality of selectable frequencies comprises frequencies in a near-infrared band.

In a tenth aspect A10, according to any preceding aspect, the plurality of selectable frequencies comprises frequencies between about 272 THz to about 430 THz.

In an eleventh aspect A11, according to any preceding aspect, a power of the first beam is greater than a power of the second beam.

In a twelfth aspect A12, a discretely tunable laser system includes a continuously tunable laser configured to output a beam tunable among a plurality of selectable frequencies, each of the plurality of selectable frequencies separated in frequency by a plurality of discrete frequency intervals, the plurality of discrete frequency intervals including a maximum frequency interval and a minimum frequency interval, wherein a difference between the maximum frequency interval and the minimum frequency interval is 100 MHz or less. An external stabilization circuit is optically coupled to the continuously tunable laser and electrically coupled to a controller, the controller controlling the tuning of the continuously tunable laser among the plurality of selectable frequencies. The external stabilization circuit includes a first tap configured to split the beam into a first beam and a second beam, a Fabry-Pérot interferometer optically coupled to the second beam, the Fabry-Pérot interferometer configured to produce a plurality of resonances equally spaced in frequency, each of the plurality of resonances defining one of the plurality of selectable frequencies, the Fabry-Pérot interferometer generates a transmission beam and a reflection beam from the second beam, a first photodiode optically coupled to the Fabry-Pérot interferometer through a second tap configured to direct the reflection beam from the Fabry-Pérot interferometer to the first photodiode, the first photodiode configured to generate a first electrical signal corresponding to a reflected power of the reflection beam reflected by the Fabry-Pérot interferometer, and a second photodiode optically coupled to the transmission beam from the Fabry-Pérot interferometer and configured to generate a second electrical signal corresponding to a transmission power of the transmission beam. The controller is configured to generate one or more tuning signals for tuning the continuously tunable laser to one of the plurality of selectable frequencies based on the first electrical signal and the second electrical signal, and transmit the one or more tuning signals to the continuously tunable laser thereby causing the continuously tunable laser to output a beam having the one of the plurality of selectable frequencies.

In a thirteenth aspect A13, according to the twelfth aspect A12, the one or more tuning signals adjust one or more tuning elements of the continuously tunable laser including at least one of a grating and a laser cavity length for outputting the beam having the one of the plurality of selectable frequencies.

In a fourteenth aspect A14, according to any preceding aspect, the controller implements a proportional-integral-derivative (PID) controller configured to control the one or more tuning signals by minimizing an error signal, the error signal is a difference between the second electrical signal corresponding to the transmission power of the transmission beam and the first electrical signal corresponding to the reflected power of the reflection beam reflected by the Fabry-Pérot interferometer.

In a fifteenth aspect A15, according to any preceding aspect, the discretely tunable laser system further comprises a differential amplifier configured to receive the first electrical signal and the second electrical signal and, in response, generate the error signal.

In a sixteenth aspect A16, according to any preceding aspect, the external stabilization circuit further comprises a third photodiode optically coupled to the transmission beam from the Fabry-Pérot interferometer and configured to generate a third electrical signal corresponding to the transmission power of the transmission beam, wherein the controller is further configured to: receive the third electrical signal, and implement a second PID controller configured to generate a tuning signal for adjusting a cavity length tuning element of the continuously tunable laser based on addition of an RMS value of the third electrical signal and the error signal.

In a seventeenth aspect A17, according to any preceding aspect, the discretely tunable laser system further comprises an isolator optically coupled to the continuously tunable laser and the first tap enabling transmission of light in one direction, from the continuously tunable laser toward the first tap.

In an eighteenth aspect A18, according to any preceding aspect, the continuously tunable laser is at least one of a grating tuned laser, an etalon tuned laser and a microelectromechanical system (MEMS) tunable vertical cavity surface emitting laser (VCSEL).

In a nineteenth aspect A19, according to any preceding aspect, the Fabry-Pérot interferometer is air spaced.

In a twentieth aspect A20, according to any preceding aspect, the plurality of selectable frequencies comprises frequencies between about 272 THz to about 430 THz.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts an example of a continuously tunable laser, according to one or more embodiments shown and described herein;

FIG. 2 schematically depicts a discretely tunable laser system, according to one or more embodiments shown and described herein;

FIG. 3 schematically depicts another embodiment of a discretely tunable laser system, according to one or more embodiments shown and described herein;

FIG. 4 depicts signal plots of the Fabry-Pérot transmission and reflection power as a function wavelength, according to one or more embodiments shown and described herein; and

FIG. 5 depicts a flowchart of an illustrative tuning process, according to one or more embodiments shown and described herein.

### DETAILED DESCRIPTION

The present disclosure is provided as an enabling teaching and can be understood more readily by reference to the following description, drawings, examples, and claims. To this end, those skilled in the relevant art will recognize and appreciate that many changes can be made to the various aspects of the embodiments described herein, while still obtaining the beneficial results. It will also be apparent that some of the desired benefits of the present embodiments can be obtained by selecting some of the features without utilizing other features. Accordingly, those skilled in the art will recognize that many modifications and adaptations are possible and can even be desirable in certain circumstances and are a part of the present disclosure. Therefore, it is to be understood that this disclosure is not limited to the specific articles, devices, systems, and methods disclosed unless otherwise specified. It is also to be understood that the terminology used herein is for the purposes of describing particular aspects only and is not intended to be limiting.

Embodiments described herein relate to discretely tunable laser systems with an externally coupled stabilization circuit. The systems and methods implement an externally optically coupled Fabry-Pérot interferometer and proportional-integral-derivative (PID) controller to keep a continuously tunable laser locked to one of the Fabry-Pérot resonance edges, thereby achieving precise steps in frequency. The architecture provides a stabilization technique to achieve better laser frequency stability than single cavity lasers and coupled cavity laser systems.

As described in more detail herein, the systems and methods provide a low cost stabilization circuit for a continuously tunable laser. This is different from some of the current lasers implemented in the MSP systems, which for example include a coupled cavity laser that inherently tunes discretely. The problem with single cavity lasers is that they do not tune discretely across frequencies that are precisely spaced. In order to address this problem, a high-resolution wavemeter is needed to precisely measure the output frequency or wavelength during tuning. High precision wavemeters are expensive and can increase the cost of a system by 50% or more.

Instead, embodiments of the present disclosure use a Fabry-Pérot interferometer externally coupled to the continuously tunable laser to provide a series of transmission peaks equally spaced in frequency (herein referred to as “equally spaced transmission peaks”). By generating signals, for example, through light detection sensors such as photodiodes, corresponding to the equally spaced transmission peaks, discrete and high precision tuning of the continuously tunable laser is achieved. In embodiments, where the Fabry-Pérot interferometer is air spaced, the transmission peaks are precisely equally spaced since the optical dispersion of air is extremely low. The optical power transmitted through the Fabry-Pérot interferometer is monitored so the continuously tunable laser can be tuned by minimizing (e.g., by zeroing) an error signal as described herein. In some embodiments, the error signal is defined by the difference between the transmission beam and the reflection beam generated by the Fabry-Pérot interferometer or the difference between the transmission beam generated by the Fabry-Pérot interferometer and a portion of the beam output by the continuously tunable laser, as described in more detail herein. A PID feedback controller can be used to minimize the error signal by tuning the continuously tuning to keep the continuously tunable laser locked to one of the Fabry-Pérot resonance edges, which is described in more detail herein.

The following will now describe the discretely tunable laser systems and methods of the present disclosure in more detail with reference to the drawings, where like numbers refer to like structures.

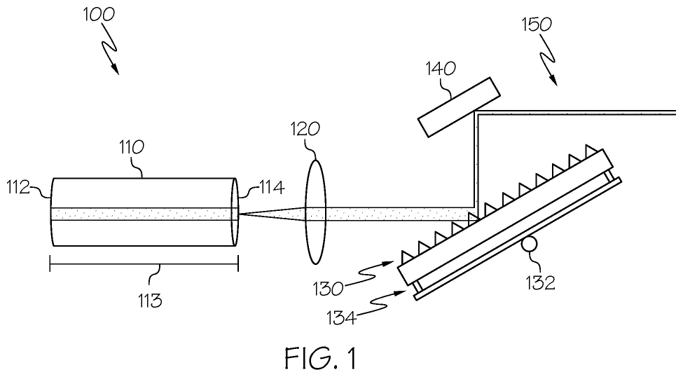

Referring to FIG. 1, an illustrative example of a continuously tunable laser 100 is depicted. Embodiments of the discretely tunable laser systems described herein include low cost stabilization circuits for continuously tunable lasers (e.g., a broadly tunable laser) so that precise (uniform) steps in frequency can be achieved while tuning over a plurality of selectable frequencies (also referred to herein as a range of wavelengths). MSP devices typically operate across a plurality of selectable frequencies, for example, in the range of the near-infrared band, optionally, from about 272 THz to about 430 THz or in wavelength terms, wavelengths in a range from 700 nm to 1100 nm. The 700 nm to 1100 nm wavelength range can be optimal for MSP devices because currently few, if any, cameras are International Traffic in Arms Regulations (ITAR) approved for near-infrared bands outside of the aforementioned range. In other words, the wavelengths of light used for measuring the flatness and thickness can be appropriately matched with imaging systems that are available on the market. However, it should be understood that for other devices and applications different ranges of wavelengths may be used. For example, the telecommunications industry may use low-loss wavelength region ranges from 1260 nm to 1625 nm, while other devices may use wavelength ranges higher or lower than the aforementioned ranges. For purposes of the present disclosure, MSP devices and wavelengths in the 700 nm to 1100 nm will be used. Additionally, for purposes of explanation and consistency when the term “frequency” is used, it should be understood to mean frequency or the wavelength equivalent.

As depicted, the continuously tunable laser 100 includes a laser diode 110, which generates light having a wavelength that may span several hundred nanometers. The laser diode 110 may include a cavity mirror 112 and an opposing cavity mirror 114 defining a cavity length by the space therebetween, which reflects and directs light generated by the laser diode 110 in a particular direction. In the present depiction, a lens 120 may be positioned in the light path from the laser diode. The lens 120 may operate to focus, collimate, and/or filter the light. A grating 130 is used to adjust the frequency of the energy (e.g., light beam 150) that is ultimately propagated from the continuously tunable laser 100. The grating 130 may include one or more tuning elements such as a stepper motor 132 for coarse adjustments to the angle of the grating and one or more piezoelectric elements (e.g., a piezoelectric actuator) for fine adjustments to the angle of the grating. As described in more detail herein, a controller generates one or more tuning signals for adjusting the tuning elements of the continuously tunable laser 100 so that a selected frequency is maintained. Since the angle of the grating 130 may be adjusted from time to time to filter out undesired frequencies and transmit desired frequencies, a beam steering mirror 140 may be situated in the continuously tunable laser 100 to direct the beam 150 out of the continuously tunable laser 100. It should be understood that continuously tunable lasers 100 may include different components and/or different configurations depending on the type of continuously tunable laser 100. The continuously tunable laser 100 may be a grating tuned laser similar to the one shown in FIG. 1, an etalon tuned laser, a microelectromechanical system (MEMs) tunable vertical cavity surface emitting laser (VCSEL) or other type of a MEMs tunable VCSEL.

One challenge for any continuously tunable laser 100 is to maintain stable single longitudinal mode operation across the tuning range. The reason is that the gain medium usually has high optical dispersion. This means that the cavity length 113 varies with frequency. To eliminate mode hopping between multiple longitudinal modes, the cavity length should be controlled to keep a cavity mode aligned to the desired wavelength and/or frequency. This can be done, in the case of a laser diode, by varying the injection current or by varying the position of one of the cavity mirror 112 and opposing cavity mirror 114. In the case of the ultra-short cavity MEMs tunable VCSELs, this is unnecessary. However in cases where mode hops need to be avoided, the controller can monitor a photodiode optically coupled to the transmission portion of the transmission beam emanating from the Fabry-Pérot interferometer as described in more detail herein.

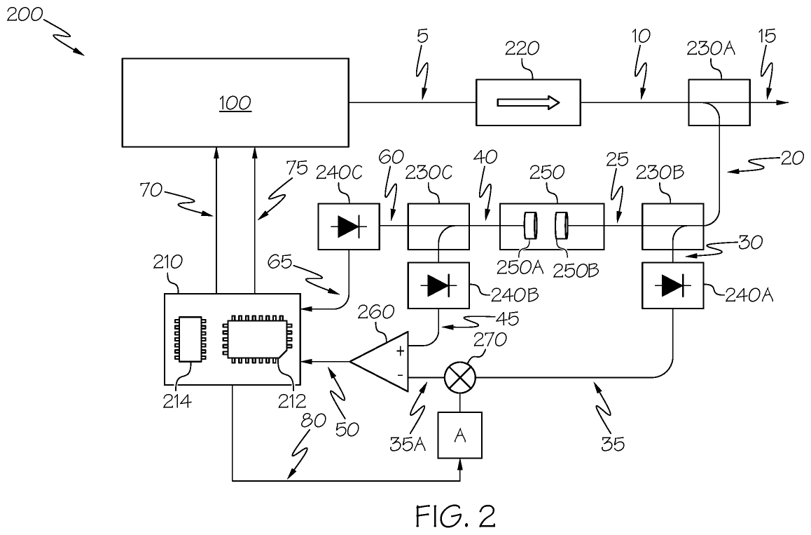

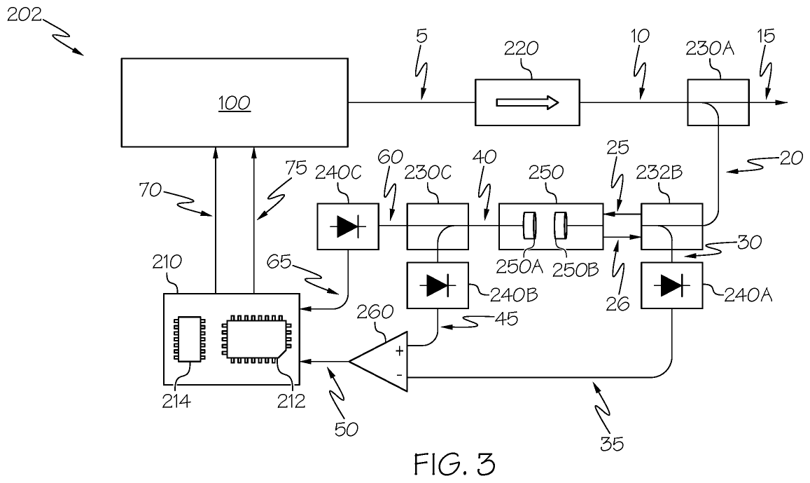

Turning now to FIGS. 2 and 3, illustrative block diagrams of example discretely tunable laser systems 200, 202 are shown. Referring to FIG. 2, the discretely tunable laser system 200 includes a continuously tunable laser 100, an external stabilization circuit and a controller 210. The external stabilization circuit is optically coupled to the continuously tunable laser 100. The controller 210 is electrically coupled to the components of the external stabilization circuit and further electrically coupled to the continuously tunable laser 100.

The controller 210 may be any device or combination of components comprising a processor 212 and the memory component 214. In some embodiments, the controller 210 may be a configuration of analog components. The processor 212 of the discretely tunable laser system 200 may be any device capable of executing the machine-readable instruction set stored in the memory component 214. Accordingly, the processor 212 may be a microcontroller, an integrated circuit, a microchip, a field programmable gate array, a computer, or any other computing device. The processor 212 is communicatively coupled to the other components of the discretely tunable laser system 200 by one or more conductive paths. Accordingly, the one or more conductive paths may communicatively couple any number of processors 212 with one another, and allow the components coupled to the one or more conductive paths to operate in a distributed computing environment. Specifically, each of the components may operate as a node that may send and/or receive data. While the embodiment depicted in FIG. 2 includes a single processor 212, other embodiments may include more than one processor 212.

The memory component 214 of the discretely tunable laser system 200 is communicatively coupled to the processor 212. The memory component 214 may be a non-transitory computer readable memory implemented as, for example, RAM, ROM, flash memories, hard drives, or any non-transitory memory device capable of storing machine-readable instructions such that the machine-readable instructions can be accessed and executed by the processor 212. The machine-readable instruction set may comprise logic or algorithm(s) written in any programming language of any generation (e.g., 1GL, 2GL, 3GL, 4GL, or 5GL) such as machine language that may be directly executed by the processor 212, or assembly language, object-oriented programming (OOP), scripting languages, microcode, etc., that may be compiled or assembled into machine readable instructions and stored in the memory component 214. Alternatively, the machine-readable instruction set may be written in a hardware description language (HDL), such as logic implemented via either a field-programmable gate array (FPGA) configuration or an application-specific integrated circuit (ASIC), or their equivalents. Accordingly, the functionality described herein may be implemented in any conventional computer programming language, as pre-programmed hardware elements, or as a combination of hardware and software components. While the discretely tunable laser system 200 depicted in FIG. 2 includes a single memory component 214, other embodiments may include more than one memory component 214.

In embodiments, the continuously tunable laser 100 generates an output beam 5. In some embodiments, the continuously tunable laser 100 is optically coupled to an isolator 220. The isolator 220 provides isolation from reflected light either from the laser output optics, the Fabry-Pérot interferometer 250, or other optics in the beam path. The isolator 220 receives the output beam 5 and further propagates the output beam 10 through the isolator 220 preventing reflections from returning to the continuously tunable laser 100. The output beam 5, 10 generated by the continuously tunable laser 100 further propagates to a first tap 230A positioned in the beam path. The first tap 230A divides output beam 10 into a first portion for lasing (e.g., lasing beam 15) and a second portion for tuning (referred to herein as a second beam 20). The power of the first portion of the output beam 10 (e.g., lasing beam 15) is greater than a power of the second portion of the output beam 10 (e.g., second beam 20).

In the embodiment of the discretely tunable laser system 200 depicted in FIG. 2, a second tap 230B is positioned in the path of second beam 20. The second tap 230B divides the second beam 20 into two separate beams, a third beam 30 and a fourth beam 25. The second tap 230B directs the fourth beam 25 to a Fabry-Pérot interferometer 250 optically coupled to the continuously tunable laser 100. In particular, it is noted that the Fabry-Pérot interferometer 250 is not an internal component of the continuously tunable laser 100. The Fabry-Pérot interferometer 250 is positioned externally from the continuously tunable laser 100. Additionally, the second tap 230B directs the third beam 30 to an optically coupled first photodiode 240A (PD1). PD1 240A generates a first electrical signal 35 corresponding to the transmission power of the third beam 30. As used herein with reference to an electrical signal generated by a photodiode from a beam, the term “corresponding to the power (or transmission power) of” means that the magnitude of the electrical signal (e.g., voltage or current) is proportional to or otherwise in a 1:1 relationship with the power (or transmission power) of the beam.

The Fabry-Pérot interferometer 250 uses the phenomenon of multiple beam interference that arises when light shines through a cavity bounded by two reflective parallel surfaces 250A and 250B. Each time the light encounters one of the surfaces, a portion of it is transmitted, and the remaining part is reflected. The net effect is to break a single beam into multiple beams that interfere with each other. If the additional optical path length of the reflected beam (due to multiple reflections) is an integral multiple of the light's frequency, then the reflected beams will interfere constructively. The Fabry-Pérot interferometer 250 provides the equally spaced resonance frequencies upon which the system tunes.

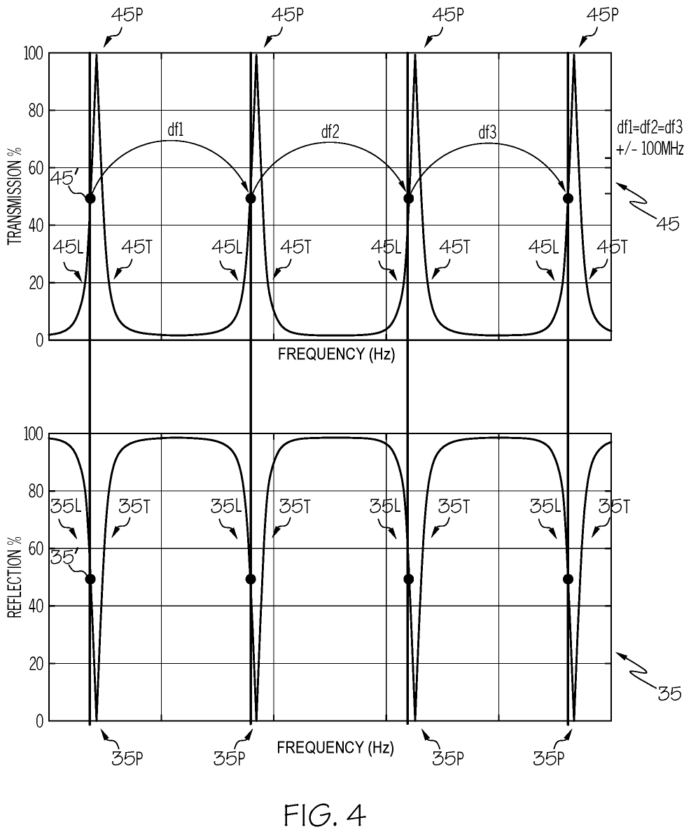

As the frequency of the continuously tunable laser 100 is varied, peaks corresponding to the resonance frequencies are transmitted through the Fabry-Pérot interferometer 250, while non-resonance frequencies are reflected. This is depicted in FIG. 4, which is discussed in more detailed herein. The transmitted resonance frequencies are referred to herein as the transmission beam 40. The transmission beam 40 transmitted from the Fabry-Pérot interferometer 250 impinges a second photodiode 240B (PD2). PD2 240B generates a second electrical signal 45 corresponding to the transmission power of the transmission beam 40. The second electrical signal 45 is a voltage signal, which may also be referred to as a percentage of transmission.

In some embodiments, a third tap 230C taps a portion of the power of the transmission beam 40 and directs the tapped transmission beam 60 to a third photodiode 240C (PD3). PD3 240C generates a third electrical signal 65 corresponding to the transmission power of the tapped transmission beam 60. That is, PD3 240C provides a reference for optical power that is used to measure noise in the laser output.

The discretely tunable laser system 200 further includes a differential amplifier 260. In the embodiment depicted in FIG. 2, the second tap 230B directs the fourth beam 25 to an optically coupled Fabry-Pérot interferometer 250. Since the fourth beam 25 is not a reflected or transmitted signal from the Fabry-Pérot interferometer 250, an amplitude adjustment to the first electrical signal 35 corresponding to the fourth beam 25 is needed before the first electrical signal 35 and the second electrical signal 45 are compared by the differential amplifier 260. Accordingly, multiplier circuit 270 injects an adjustment value A into the first electrical signal 35 generating an amplitude-adjusted first electrical signal 35A that is fed into the differential amplifier 260. The adjustment value A is set so that the amplitude-adjusted first electrical signal 35A is one-half of the peak value of the second electrical signal 45.

The differential amplifier 260 (e.g., an operational amplifier) receives the amplitude-adjusted first electrical signal 35A (e.g., A*(PD1)) and the second electrical signal 45 (e.g., PD2) and determines the difference between the second electrical signal 45 (e.g., PD2) and the amplitude-adjusted first electrical signal 35A (e.g., A*PD1). The output of the differential amplifier 260 is an error signal 50 that is transmitted to the controller 210. In some embodiments, the controller 210 receives the amplitude-adjusted first electrical signal 35A (e.g., A*(PD1)) and the second electrical signal 45 (e.g., PD2). The controller 210 determines the difference between the two signals, for example, the second electrical signal 45 minus the amplitude-adjusted first electrical signal 35A, to compute an error signal 50.

To set the adjustment value A, a user may set the output frequency of beam 5 of the continuously tunable laser 100 to correspond with a resonance frequency of the Fabry-Pérot interferometer 250 and measure the peak value of the first electrical signal 35 and the second electrical signal 45 (e.g., PD2). Then the adjustment value A can be set by solving A*PD1(peak voltage)=½ PD2(peak voltage) for A. The adjustment value A may be set by the controller 210 through signal 80. In some embodiments, the amplitude-adjusted first electrical signal 35A fed to the negative terminal of differential amplifier 260 is set at 50% of the maximum value of the signal 45, whereby the implementation of the adjustment value A described herein is one way to accomplish setting the value of the signal fed into the differential amplifier.

One or more proportional-integral-derivative (PID) controllers are implemented to generate tuning signals for adjusting the continuously tunable laser 100. For example, the controller 210 may be configured to implement a PID controller. A first PID controller is implemented to minimize an error signal 50 by generating one or more tuning signals 70, 75 that adjust the tuning elements of the continuously tunable laser 100 in order to minimize the error signal 50. Tuning elements of the continuously tunable laser 100 include at least one of a grating, a filter, a laser cavity length or other optical elements known in the art for varying the frequency of the beam 5 by the continuously tunable laser 100.

In embodiments, once the controller 210 generates the one or more tuning signals 70, 75, the controller 210 transmits the one or more tuning signals 70, 75 to the continuously tunable laser 100 causing one or more tuning elements to be adjusted and the continuously tunable laser 100 to output a beam 5 having a selectable frequency.

The PID controller operates by locking to a zero crossing in the error signal 50. By subtracting the second electrical signal 45 corresponding to the transmission power of the transmission beam 40 and an amplitude-adjusted first electrical signal 35A corresponding to the adjusted transmission power of the third beam 30, an error signal 50 is generated and can be minimized (e.g., to zero) through tuning of the frequency of the beam 5 of the continuously tunable laser 100. This happens on both the leading edge and the trailing edge of the Fabry-Pérot resonance, which will be described in more detail herein.

In some embodiments of the discretely tunable laser system 200, the controller 210 may also receive a third electrical signal 65 generated by the third photodiode 240C (PD3) which corresponds to a tapped portion of the transmission beam 40 transmitted from the Fabry-Pérot interferometer 250, which is referred to herein as the tapped transmission beam 60. The third electrical signal 65 provides a reference for power and can be used to measure noise in the output of the continuously tunable laser 100. The controller 210 is configured to monitor the noise or root mean square (RMS) values in the third electrical signal 65 for evidence of mode hopping. With the third electrical signal 65, the controller 210 may improve control of the continuously tunable laser 100 by adding the RMS of the third electrical signal 65 to the error signal 50. A second PID controller may be implemented to drive the noise in the third electrical signal 65 to zero through a feedback loop that includes generating a tuning signal 75 for controlling and/or adjusting a cavity length tuning element of the continuously tunable laser 100. This ensures that a cavity mode is aligned to the desired selectable frequency.

In some instances, when operating a first PID controller and a second PID controller, mode pulling may occur. Mode pulling occurs in laser systems without an ultrashort cavity and with a wavelength selective element. That is, the laser may lase at a wavelength that is between the wavelength of the tuning element and the wavelength of the nearest cavity mode. As such, multiple PID controllers may counteract each other and result in instability of the output wavelength. To avoid this, one PID controller may be filtered to low frequency and set to have a much slower response than another PID controller. For example, the controller response speeds may differ by at least a factor of 10×, for example. As with a wavelength tuning element, a cavity length tuning element can be calibrated during manufacturing and the results can be used to provide a feedforward signal for faster and more robust tuning.

Turning now to FIG. 3, another illustrative block diagram of a discretely tunable laser system 202 is shown. The discretely tunable laser system 202 depicted in FIG. 3 is similarly configured to the discretely tunable laser system 200 depicted in FIG. 2. Accordingly, only differences between the two discretely tunable laser systems 200 and 202 will be described.

In particular, instead of the second tap 230B of the discretely tunable laser system 200 depicted in FIG. 2 being positioned to tap the second beam 20, the second tap 232B of the discretely tunable laser system 202 depicted in FIG. 3 is positioned to tap a reflected optical signal referred to herein as a reflection beam 26 from the Fabry-Pérot interferometer 250. The second tap 232B directs the second beam 20 to an optically coupled Fabry-Pérot interferometer 250 as the fourth beam 25 and directs the reflection beam 26 generated by the Fabry-Pérot interferometer 250 to the optically coupled first photodiode 240A (PD1). PD1 240A generates a first electrical signal 35 corresponding to the power of the reflection beam 26 from the Fabry-Pérot interferometer 250.

Referring still to FIG. 3, the differential amplifier 260 receives the first electrical signal 35 (e.g., generated by PD1) and the second electrical signal 45 (e.g., generated by PD2) and determines the difference between the second electrical signal 45 and the first electrical signal 35. It is not necessary for the discretely tunable laser system 202 to precondition the first electrical signal 35 with an adjustment value A as described with reference to first discretely tunable laser system 200.

Turning to FIG. 4 an illustrative example of signal plots of the Fabry-Pérot transmission and reflection power as a function of frequency are depicted. The transmission plot (top) illustrates an example of the second electrical signal 45 generated by the second photodiode 240B (PD2). The reflection plot (bottom) illustrates an example of the first electrical signal 35 generated by the first photodiode 240A (PD1) as implemented in the discretely tunable laser system 202. Additionally, a plot, which is not shown, of the amplitude-adjusted electrical signal 35A generated by the first photodiode 240A (PD1) as implemented in the discretely tunable laser system 200 may generally resemble a bell curve shape extending a tuning range selected for the continuously tunable laser 100. That is, power represented by the bell curve shape is proportional to the output power of the continuously tunable laser 100 and is independent of the Fabry-Pérot transmission and reflection power. For example, the center of the tuning range of the output beam 5, a portion of which is tapped and directed the first photodiode 240A (PD1) as implement in the discretely tunable laser system 200, includes the majority of the power which tails off approaching the ends of the tuning range.

Referring specifically to the plots depicted in FIG. 4 and with reference to the discretely tunable laser system 202 depicted in FIG. 3, the reflection percentage and transmission percentage correspond respectively to voltage signal values generated by the first photodiode 240A (PD1) for the reflected signal and the second photodiode 240B (PD2) for the transmitted signal, where reflection percentage and transmission percentage are relative to the maximum voltage signal values from first photodiode 240A (PD1) and second photodiode 240B (PD2), respectively. The PID controller operates by locking to a zero crossing in the error signal. In some embodiments, locking may be accomplished by selecting a particular frequency point 45′ along the leading edge 45L, the peak 45P, or trailing edge 45T of the transmitted signal (e.g., the second electrical signal 45) and identifying the corresponding frequency point 35′ in the reflected signal (e.g., the first electrical signal 35 with respect to the discretely tunable laser system 202) or the amplitude-adjusted electrical signal 35A generated by the first photodiode 240A (PD1) as implemented in the discretely tunable laser system 200. By subtracting the transmitted signal (e.g., the second electrical signal 45) from the reflected signal (e.g., the first electrical signal 35) or vice versa, the controller generates an error signal that is zero when they are equal (e.g., the reflection percentage and the transmission percentage both equal 50%). Depending on the sign used to drive the tuning elements that control frequency of the output beam 5 (e.g., also referred to as the wavelength of the beam 5) and cavity stability, a choice can be made between which of the edges (e.g., the leading edge 45L, 35L or trailing edge 45T, 35T) to lock.

Adjustment of the one or more tuning elements of the continuously tunable laser 100 modifies the frequency of the beam 5 produced by the continuously tunable laser 100. The frequency of the beam 5 of the continuously tunable laser 100 that minimizes the error signal 50 is referred to herein as a “selectable frequency”. As is evident from FIG. 4, the continuously tunable laser 100 has a plurality of selectable frequencies. Each resonance peak 45P of Fabry-Pérot interferometer 250 has two selectable frequencies, one on the leading edge 45L and one on the trailing edge 45T. To maintain uniformity of frequency spacing when discretely tuning the continuously tunable laser 100, it is preferred that the selectable frequencies are all associated with only the leading edge 45L or only the trailing edge 45T of each of the resonance peaks 45P. In the illustrative embodiment of FIG. 4, the selectable frequencies are defined by the leading edges 45L of the resonance peaks 45P as depicted. Four resonance peaks 45P are depicted in FIG. 4 and a selectable frequency is depicted by a dot (e.g., frequency point 45′) on the leading edge 45L of each of the four resonance peaks 45P. The labels “df1”, “df2” and “df3” define frequency spacings between consecutive resonance peaks 45P within the set of the four depicted resonance peaks 45P. The frequency spacings df1, df2, and df3 are equal to within the tolerance described herein (e.g., +/−100 MHz or less).

The device in the laser that controls wavelength of the beam 5 is typically a filter, such as a Fabry-Pérot etalon or a grating. MEMs tunable VCSELs can also be used. One mirror in the laser cavity is driven by a MEMs actuator. This varies the length of the cavity and moves the wavelength at which the VCSEL can lase. Because the cavity is extremely short, the free spectral range of these Fabry-Pérot cavity modes is greater than the gain bandwidth of the laser. That means that the only mode which will lase is the mode within the gain bandwidth of the VCSEL diode and the wavelength of this mode can be tuned by simply tuning the length of the cavity with the MEMs actuator.

Whatever the mechanism used for tuning the laser wavelength of the continuously tunable laser, the tuning signal will be driven by the output of a PID controller (e.g., implemented by controller 210) whose error signal is the difference between the electrical signals associated with the reflected and transmitted powers from the externally positioned Fabry-Pérot interferometer 250. By doing so, the discretely tunable laser systems 200, 202 can precisely jump, and lock on, to wavelengths. The wavelength spacing, or frequency spacing, is determined by the spacing of the resonances of the external Fabry-Pérot interferometer 250. Fabry-Pérot interferometer 250 may have a frequency spacing in the range of a few gigahertz, tens of gigahertz, or hundreds of gigahertz. For example, the frequency spacing may be 200 MHz, 250 MHz, 500 MHz, 1 GHz, 2 GHz, 5 GHz, 10 GHz, 20 GHz, 20 GHz, 25 GHz, 30 GHz, 35 GHz, 40 GHz, 50 GHz, or a value between 200 MHz and 50 GHz. As noted hereinabove, the goal is to lock the frequency of the output beam 5 of the continuously tunable laser 100 to each of a series of frequencies separated by a frequency spacing that is constant to within +/−100 MHz or less; such as, for example to within +/−100 MHz or within +/−75 MHz or within +/−50 MHz or within +/−25 MHz or within +/−10 MHz. That is, for example, at higher frequencies of the output beam 5 a larger range may be achieved, while at lower frequencies of the output beam 5 a narrower range such as +/−10 MHz is desirable and achievable with the present embodiments. In other words, as the frequency of the output beam 5 decreases the range correspondingly scales.

When the Fabry-Pérot interferometer 250 is based on an air-spaced etalon, there is virtually zero dispersion over the frequency tuning range, which facilitates a constant frequency spacing across the tuning range of the continuously tunable laser 100. This is important for measurement devices that depend on interferometric measurements at equally spaced frequencies. If the finesse of the Fabry-Pérot interferometer is high, the resonances will be very sharp and will be able to lock to frequencies that are spaced with very high consistency and precision across the tuning range.

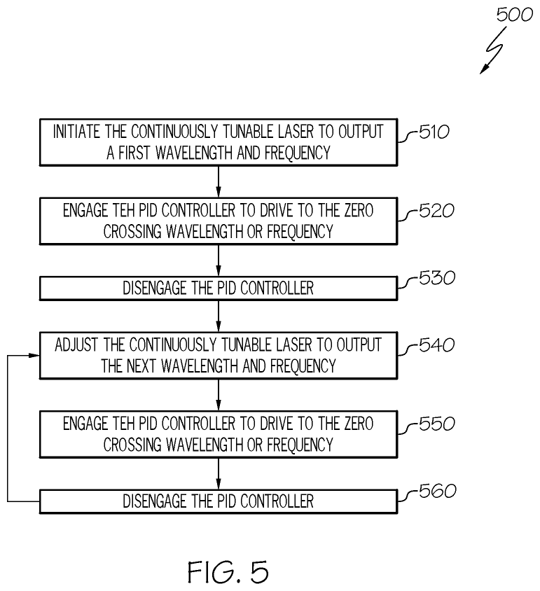

Turning to FIG. 5, a flowchart 500 depicting an illustrative tuning process is depicted. At block 510, the continuously tunable laser 100 is initiated. Initiation, for example, includes powering on the laser and providing a tuning signal to tune the tuning elements to initial positions for a selected frequency output of the output beam. At block 520, the PID controller in the controller 210 may be engaged. As described herein, the PID controller generates tuning signals that adjust the tuning elements of the continuously tunable laser 100 to drive the error signal to a zero crossing frequency. At block 530, the PID controller may be disengaged. Once disengaged, the controller 210 may coarsely adjust the tuning elements of the continuously tunable laser 100 to the next frequency at block 540. At block 550, the PID controller in the controller 210 is reengaged to finely tune the continuously tunable laser 100 again. At block 560, the PID controller is disengaged again and the tuning process returns to block 540 if additional tuning is need. This process is repeated across the tuning range/bandwidth of the continuously tunable laser 100. The roughly correct settings for the drive signal for the wavelength/frequency tuning element can be determined ahead of time through a calibration process and that signal can be used as a feed-forward value to add to the output of the PID controller.

It should now be understood that a continuously tunable laser may be optically coupled to an externally located Fabry-Pérot interferometer to provide a discretely tunable laser system with stabilization. For example, in some embodiments, the discretely tunable laser system includes a continuously tunable laser configured to output a beam tunable among a plurality of selectable frequencies, the selectable frequencies separated in frequency by a plurality of discrete frequency intervals, the plurality of discrete frequency intervals including a maximum frequency interval and a minimum frequency interval, wherein a difference between the maximum frequency interval and the minimum frequency interval is 100 MHz or less. An external stabilization circuit is optically coupled to the continuously tunable laser and electrically coupled to a controller, the controller controlling the tuning of the continuously tunable laser among the plurality of selectable frequencies. The external stabilization circuit includes a first tap configured to split the beam into a first beam and a second beam, a second tap configured to split the second beam into a third beam and a fourth beam; a first photodiode configured to generate a first electrical signal corresponding to a transmission power of the third beam, a Fabry-Pérot interferometer configured to produce a plurality of resonances upon incidence of the fourth beam, the plurality of resonances equally spaced in frequency, each of the plurality of resonances defining one of the plurality of selectable frequencies, the Fabry-Pérot interferometer generating a transmission beam from the fourth beam, and a second photodiode configured to generate a second electrical signal corresponding to a transmission power of the transmission beam from the Fabry-Pérot interferometer. The controller is configured to generate one or more tuning signals for tuning the continuously tunable laser to one of the plurality of selectable frequencies based on the first electrical signal and the second electrical signal, and transmit the one or more tuning signals to the continuously tunable laser thereby causing the continuously tunable laser to output a beam having the one of the plurality of selectable frequencies.

In some embodiments, the controller implements a proportional-integral-derivative (PID) controller configured to minimize an error signal to generate the one or more tuning signals, the error signal is a difference between the second electrical signal corresponding to the transmission power of the transmission beam and a calibrated multiple of the first electrical signal corresponding to the transmission power of the second portion of the beam. Additionally, in some embodiments, the external stabilization circuit further includes a third photodiode optically coupled the transmission beam from the Fabry-Pérot interferometer. The third photodiode may be implemented to improve locking of the PID controller. That is, for a good lock the same fraction of output power needs to be maintained. Through the electrical signal generated by the third photodiode, the controller may monitor the output power and if the power goes up or down between steps, then the controller can adjust the locking point linearly by the same percentage increase or decrease.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A discretely tunable laser system comprising:
a continuously tunable laser configured to output a beam tunable among a plurality of selectable frequencies, each of the plurality of selectable frequencies being separated in frequency by a plurality of discrete frequency intervals, the plurality of discrete frequency intervals including a maximum frequency interval and a minimum frequency interval, wherein a difference between the maximum frequency interval and the minimum frequency interval is 100 MHz or less; and
an external stabilization circuit optically coupled to the continuously tunable laser and electrically coupled to a controller, the controller controlling the tuning of the continuously tunable laser among the plurality of selectable frequencies, the external stabilization circuit comprising:
a first tap configured to split the beam into a first beam and a second beam,
a second tap configured to split the second beam into a third beam and a fourth beam,
a first photodiode configured to generate a first electrical signal corresponding to a transmission power of the third beam,
a Fabry-Pérot interferometer configured to produce a plurality of resonances upon incidence of the fourth beam, the plurality of resonances equally spaced in frequency, each of the plurality of resonances defining one of the plurality of selectable frequencies, the Fabry-Pérot interferometer generating a transmission beam from the fourth beam, and
a second photodiode configured to generate a second electrical signal corresponding to a transmission power of the transmission beam from the Fabry-Pérot interferometer,
wherein the controller is configured to:
generate one or more tuning signals for tuning the continuously tunable laser to one of the plurality of selectable frequencies based on the first electrical signal and the second electrical signal, and
transmit the one or more tuning signals to the continuously tunable laser thereby causing the continuously tunable laser to output another beam having the one of the plurality of selectable frequencies.

2. The discretely tunable laser system of claim 1, wherein the one or more tuning signals adjust one or more tuning elements of the continuously tunable laser including at least one of a grating and a laser cavity length for outputting the beam having the one of the plurality of selectable frequencies.

3. The discretely tunable laser system of claim 1, wherein the controller implements a proportional-integral-derivative (PID) controller configured to control the one or more tuning signals by minimizing an error signal, wherein the error signal is a difference between the second electrical signal corresponding to the transmission power of the transmission beam from the Fabry-Pérot interferometer and an amplitude adjusted first electrical signal of the first electrical signal corresponding to the transmission power of the third beam.

4. The discretely tunable laser system of claim 3, further comprising a differential amplifier configured to receive the amplitude adjusted first electrical signal and the second electrical signal and, in response, generate the error signal.

5. The discretely tunable laser system of claim 3, wherein the external stabilization circuit further comprises a third photodiode optically coupled to the transmission beam from the Fabry-Pérot interferometer and configured to generate a third electrical signal corresponding to the transmission power of the transmission beam,
wherein the controller is further configured to:
receive the third electrical signal, and
implement a second PID controller configured to generate a tuning signal for adjusting a cavity length tuning element of the continuously tunable laser based on addition of an RMS value of the third electrical signal and the error signal.

6. The discretely tunable laser system of claim 1, further comprising an isolator optically coupled to the continuously tunable laser and the first tap enabling transmission of light in one direction, from the continuously tunable laser toward the first tap.

7. The discretely tunable laser system of claim 1, wherein the continuously tunable laser is at least one of a grating tuned laser, an etalon tuned laser, and a microelectromechanical system (MEMs) tunable vertical cavity surface emitting laser (VCSEL).

8. The discretely tunable laser system of claim 1, wherein the Fabry-Pérot interferometer is air spaced.

9. The discretely tunable laser system of claim 1, wherein the plurality of selectable frequencies comprises frequencies in a near-infrared band.

10. The discretely tunable laser system of claim 1, wherein the plurality of selectable frequencies comprises frequencies between about 272 THz to about 430 THz.

11. The discretely tunable laser system of claim 1, wherein a power of the first beam is greater than a power of the second beam.

12. A discretely tunable laser system, comprising:
a continuously tunable laser configured to output a beam tunable among a plurality of selectable frequencies, each of the plurality of selectable frequencies separated in frequency by a plurality of discrete frequency intervals, the plurality of discrete frequency intervals including a maximum frequency interval and a minimum frequency interval, wherein a difference between the maximum frequency interval and the minimum frequency interval is 100 MHz or less; and
an external stabilization circuit optically coupled to the continuously tunable laser and electrically coupled to a controller, the controller controlling the tuning of the continuously tunable laser among the plurality of selectable frequencies, the external stabilization circuit comprising:
a first tap configured to split the beam into a first beam and a second beam,
a Fabry-Pérot interferometer optically coupled to the second beam, the Fabry-Pérot interferometer configured to produce a plurality of resonances equally spaced in frequency, each of the plurality of resonances defining one of the plurality of selectable frequencies, wherein the Fabry-Pérot interferometer generates a transmission beam and a reflection beam from the second beam,
a first photodiode optically coupled to the Fabry-Pérot interferometer through a second tap configured to direct the reflection beam from the Fabry-Pérot interferometer to the first photodiode, the first photodiode configured to generate a first electrical signal corresponding to a reflected power of the reflection beam reflected by the Fabry-Pérot interferometer, and
a second photodiode optically coupled to the transmission beam from the Fabry-Pérot interferometer and configured to generate a second electrical signal corresponding to a transmission power of the transmission beam,
wherein the controller is configured to:
generate one or more tuning signals for tuning the continuously tunable laser to one of the plurality of selectable frequencies based on the first electrical signal and the second electrical signal, and
transmit the one or more tuning signals to the continuously tunable laser thereby causing the continuously tunable laser to output another beam having the one of the plurality of selectable frequencies.

13. The discretely tunable laser system of claim 12, wherein the one or more tuning signals adjust one or more tuning elements of the continuously tunable laser including at least one of a grating and a laser cavity length for outputting the beam having one of the plurality of selectable frequencies.

14. The discretely tunable laser system of claim 12, wherein the controller implements a proportional-integral-derivative (PID) controller configured to control the one or more tuning signals by minimizing an error signal, wherein the error signal is a difference between the second electrical signal corresponding to the transmission power of the transmission beam and the first electrical signal corresponding to the reflected power of the reflection beam reflected by the Fabry-Pérot interferometer.

15. The discretely tunable laser system of claim 14, further comprising a differential amplifier configured to receive the first electrical signal and the second electrical signal and, in response, generate the error signal.

16. The discretely tunable laser system of claim 14, wherein the external stabilization circuit further comprises a third photodiode optically coupled to the transmission beam from the Fabry-Pérot interferometer and configured to generate a third electrical signal corresponding to the transmission power of the transmission beam,
wherein the controller is further configured to:
receive the third electrical signal, and
implement a second PID controller configured to generate a tuning signal for adjusting a cavity length tuning element of the continuously tunable laser based on addition of an RMS value of the third electrical signal and the error signal.

17. The discretely tunable laser system of claim 12, further comprising an isolator optically coupled to the continuously tunable laser and the first tap enabling transmission of light in one direction, from the continuously tunable laser toward the first tap.

18. The discretely tunable laser system of claim 12, wherein the continuously tunable laser is at least one of a grating tuned laser, an etalon tuned laser, and a microelectromechanical system (MEMs) tunable vertical cavity surface emitting laser (VCSEL).

19. The discretely tunable laser system of claim 12, wherein the Fabry-Pérot interferometer is air spaced.

20. The discretely tunable laser system of claim 12, wherein the plurality of selectable frequencies comprises frequencies between about 272 THz to about 430 THz.
